(19) United States
(12) Patent Application Publication
(10) Pub. No.: US 2025/0386679 A1
(43) Pub. Date: Dec. 18, 2025

(54) DISPLAY PANEL, METHOD OF MANUFACTURING THE SAME AND DISPLAY DEVICE

(71) Applicant: HKC CORPORATION LIMITED, SHENZHEN (CN)

(72) Inventors: Qin LIANG, SHENZHEN (CN); Xiufeng ZHOU, SHENZHEN (CN); Zhisheng XIE, SHENZHEN (CN); Yangling TANG, SHENZHEN (CN); Lidan YE, SHENZHEN (CN)

(73) Assignee: HKC CORPORATION LIMITED, SHENZHEN (CN)

(21) Appl. No.: 19/235,043

(22) Filed: Jun. 11, 2025

(30) Foreign Application Priority Data
Jun. 14, 2024 (CN) 202410775521.8

(51) Int. Cl. H10K 59/122; H10K 59/12

(52) U.S. Cl. CPC H10K 59/122; H10K 59/1201

(57) ABSTRACT

The present application provides a display panel, a manufacturing method of a display panel, and a display device. The display panel includes: a substrate, including a signal line; a plurality of sub-pixels, arranged on the substrate; a pixel defining layer, arranged on the substrate, and configured to limit positions of the plurality of sub-pixels; an isolation structure, arranged on a side of the pixel defining layer away from the substrate, and configured to isolate the plurality of sub-pixels; where a first chamfer structure is provided at connection between the isolation structure along the first direction and the isolation structure along the second direction, and the substrate is provided with an anode hole located in a shielding area formed by a corresponding isolation structure and the first chamfer structure, and an anode of at least one of the plurality of sub-pixels is connected to the signal line through the anode hole.

### CROSS-REFERENCE TO RELATED APPLICATIONS

The present disclosure claims priority of Chinese Patent Application No. 202410775521.8,entitled “DISPLAY PANEL, METHOD OF MANUFACTURING THE SAME AND DISPLAY DEVICE”, filed on Jun. 14, 2024, the contents of which are hereby incorporated by reference.

### TECHNICAL FIELD

The present disclosure relates to the field of display technologies, and in particular, to a display panel, a manufacturing method of a display panel and a display device.

### BACKGROUND

In an active-matrix organic light-emitting diode (AMOLED) display panel, a drive organic light-emitting diode (OLED) is driven to emit light through a thin-film transistor (TFT). In an existing display product, a light-emitting area is driven to emit light through pixel units of an array. Sub-pixel light-emitting units of a conventional array are prepared using a fine metal mask (FMM) evaporation process. At present, a conductive isolation structure can be adopted as an alternative to the traditional FMM process. The conductive isolation structure is arranged around each sub-pixel to facilitate FMM-free evaporation of the electroluminescent (EL) layer and to form a conductive network across the entire surface for transmitting cathode signals. In the design of the pixel layer structure with the conductive isolation structure, the lower TFT device needs to be connected to the upper pixel anode through a via design to enable signal transmission. In a design process of a pixel film structure with a conductive isolation structure, a lower TFT needs to be connected to an upper pixel anode through a hole to form signal transmission.

### SUMMARY

According to a first aspect, some embodiments of the present disclosure provide a display panel. The display panel includes: a substrate, including a signal line; a plurality of sub-pixels, arranged on the substrate; a pixel defining layer, arranged on the substrate, and configured to limit positions of the plurality of sub-pixels; an isolation structure, arranged on a side of the pixel defining layer away from the substrate, and configured to isolate the plurality of sub-pixels; where a first chamfer structure is provided at connection between the isolation structure along the first direction and the isolation structure along the second direction, and the substrate is provided with an anode hole located in a shielding area formed by a corresponding isolation structure and the first chamfer structure, and an anode of at least one of the plurality of sub-pixels is connected to the signal line through the anode hole.

According to a second aspect, the present disclosure also provides a manufacturing method of a display panel, including: providing a substrate, where the substrate includes a signal line, and is provided with an anode hole; forming an anode of a sub-pixel on the substrate, where anode of at least one of a plurality of sub-pixels is connected to the signal line through the anode hole; forming a pixel defining layer on the substrate, where the pixel defining layer is configured to define positions of the plurality of sub-pixels, and the pixel defining layer at least covers the anode hole; forming an isolation structure on the pixel defining layer, where the isolation structure is configured to isolate the plurality of sub-pixels; a first chamfer structure is provided at connection between the isolation structure along the first direction and the isolation structure along the second direction, and the anode hole is located in a shielding area formed by the corresponding isolation structure and the chamfer structure.

According to a third aspect, some embodiments of the present disclosure also provide a display device including aa display panel and a power supply for supplying power to the display panel. The display panel is the display panel as described in any one of the above embodiments, or the display panel made by the manufacturing method as described in the above embodiments.

### BRIEF DESCRIPTION OF THE DRAWINGS

In order to more clearly illustrate the technical solutions in the embodiments of the present disclosure, a brief description of the accompanying drawings to be used in the description of the embodiments will be given below. It will be obvious that the accompanying drawings in the following description are only some embodiments of the present disclosure, and that other accompanying drawings may be obtained on the basis of these drawings without any creative effort for those skilled in the art.

FIG. 1 is a top view of a first embodiment of a display panel according to the present disclosure.

FIG. 2 is a top view of a second embodiment of a display panel according to the present disclosure.

FIG. 3 is a schematic view of a first example structure of FIG. 1.

FIG. 4 is a schematic view of a second example structure of FIG. 1.

FIG. 5 is a cross-sectional schematic view of a sub-pixel I-I area in FIG. 4.

FIG. 6 is a cross-sectional schematic view of a sub-pixel II-II area in FIG. 4.

FIG. 7 is a cross-sectional schematic view of a sub-pixel III-III area in FIG. 1 according to a first embodiment.

FIG. 8 is a cross-sectional schematic view of a sub-pixel III-III area in FIG. 1 according to a second embodiment.

FIGS. 9a to 9d are schematic views of positions of anode holes A in sub-pixel arrangement of a display panel according to a first embodiment of the present disclosure.

FIGS. 10a-10c are schematic views of positions of anode holes A in sub-pixel arrangement of a display panel according to a second embodiment of the present disclosure.

FIG. 11 is a flowchart of an embodiment of a manufacturing method of a display panel according to the present disclosure.

FIGS. 12a-12c are schematic views of a process in FIG. 11.

FIG. 13 is a flowchart of subsequent operations after operations at block S40 in FIG. 11.

FIG. 14 is a schematic view of an embodiment of a display device according to the present disclosure.

### DETAILED DESCRIPTION OF THE PREFERRED EMBODIMENTS

The technical solutions in the embodiments of the present disclosure will be clearly and completely described below with reference to the drawings in the embodiments of the present disclosure. Apparently, the described embodiments are only a part of the embodiments of the present disclosure, not all of the embodiments. All other embodiments obtained by those skilled in the art based on the embodiments of the present disclosure without creative efforts shall fall within the protection scope of the present disclosure.

The terms “first”, “second” and the like in the present disclosure are used to distinguish different objects, rather than to describe a specific order. In addition, the terms “comprise” and “include” and any variations of the two terms are intended to cover exclusive inclusion. For example, a process, method, system, product or device comprising a series of steps or modules is not limited to the listed steps or modules, but some embodiments also include steps or modules not listed, or some embodiments also include other steps or modules inherent to these processes, methods, products or devices.

Reference to “embodiments” herein means that specific features, structures or characteristics described the embodiments may be included in at least one embodiment of the present disclosure. The presence of the term in various places in the description does not necessarily refer to the same embodiment, nor is it an independent or alternative embodiment mutually exclusive with other embodiments. It is explicitly and implicitly understood by those skilled in the art that the embodiments described herein may be combined with other embodiments.

With the gradual development of a display panel, in order to make sub-pixels of each color sufficiently dispersed in a display screen of the display panel, and to make the display screen more delicate, the sub-pixels of each color are usually cyclically arranged along a first direction in sequence, and the sub-pixels of the same color in adjacent rows of sub-pixels are staggered in the second direction, ensuring that there is no excessively large monochrome pixel block composed of at least two identical sub-pixels in the display panel, thereby ensuring the resolution of the display screen. The drawback of related art is that the human eye is usually more sensitive to the light emitted by sub-pixels of a certain color among sub-pixels of all colors. However, in the condition where the number of sub-pixels of each color in each pixel group is the same, the number of sub-pixels of the most sensitive color perceived by the human eye will be the same as the number of sub-pixels of any color perceived less sensitive by the human eye, resulting in poor display performance of the display panel. In addition, in condition that the number of sub-pixels of the most sensitive color perceived by the human eye is directly increased in each pixel group, although it can increase a pixel density of specific color sub-pixels, it will also lead to an increase in a non-display area occupied by anode lines and anode holes that need to be configured in each pixel group, thereby causing aperture ratio of the display panel to decrease. It can be seen that the existing display panel cannot increase the pixel density of the sub-pixels of the specific color while ensuring a high aperture ratio, resulting in poor display performance of the existing display panel.

Therefore, in pixel design, the position of the anode hole needs to be fully considered. The anode hole should preferably occupy original non-luminous area. At the same time, a conductive isolation structure should be designed in combination to improve the light-emitting effect of the product. Therefore, the present disclosure provides a display panel, a manufacturing method of a display panel and a display device to solve the above-mentioned problems.

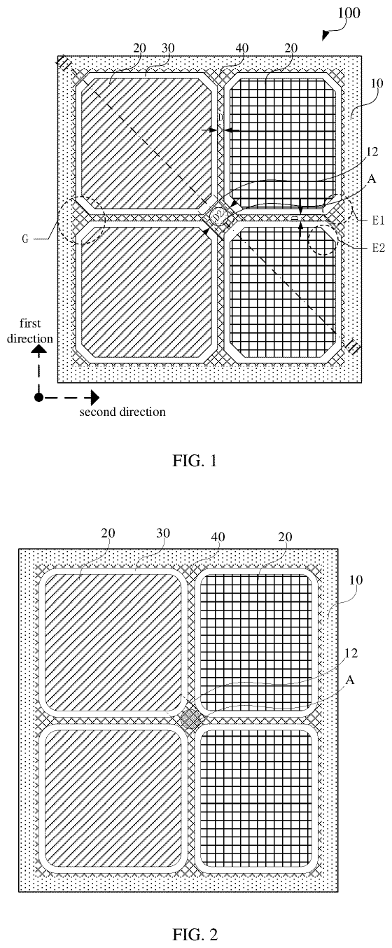

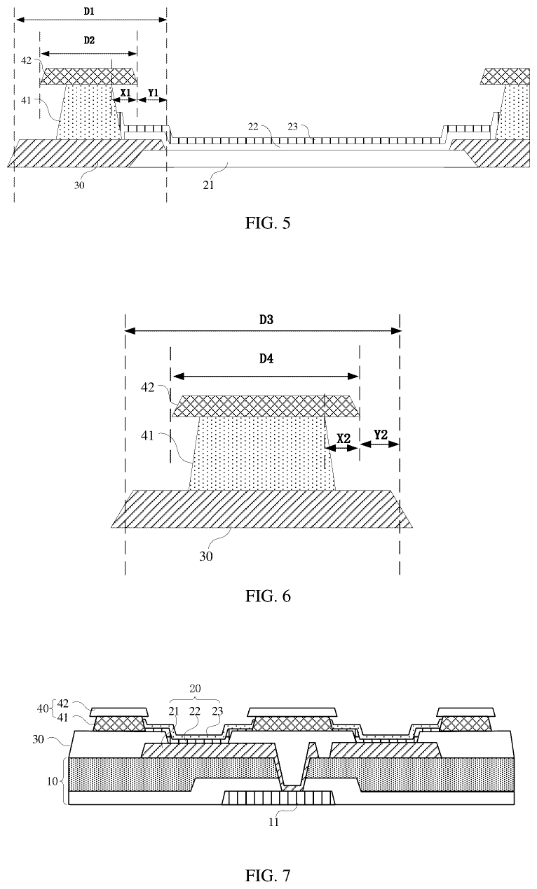

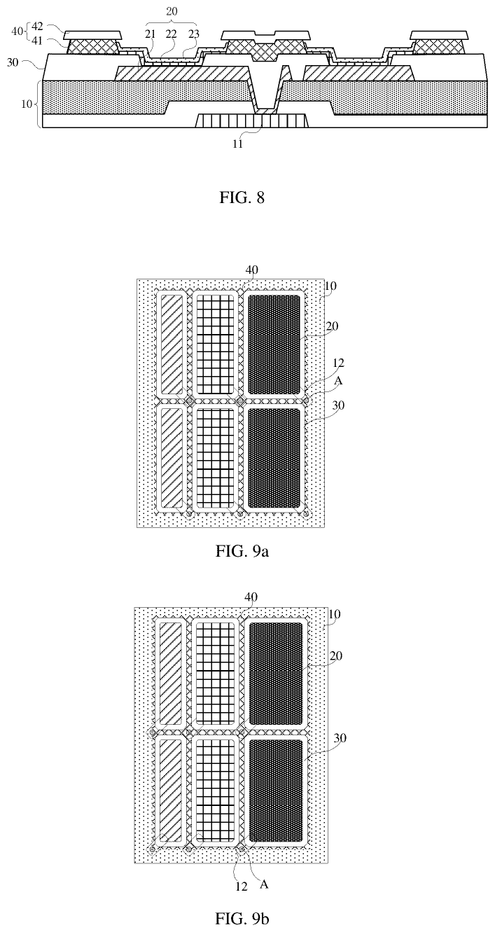

As shown in FIG. 1, FIG. 1 is a top view of a first embodiment of a display panel according to the present disclosure. The display panel 100 includes: a substrate 10, a plurality of sub-pixel 20, a pixel defining layer 30, and an isolation structure 40. Specifically, as shown in FIG. 7 and FIG. 8, the substrate 10 includes a signal line 11. The plurality of sub-pixels 20 are arranged on the substrate 10. The pixel defining layer 30 is arranged on the substrate 10 and is configured to limit positions of the plurality of sub-pixels 20. The isolation structure 40 is arranged on a side of the pixel defining layer 30 away from the substrate 10 and is configured to isolate the plurality of sub-pixels 20. A first chamfer structure E1 is provided at connection G between the isolation structure 40 along a first direction and the isolation structure 40 along a second direction, and the substrate is provided with an anode hole A. The anode hole A is located in a shielding area formed by the corresponding isolation structure 40 and the first chamfer structure E1. Referring to FIG. 5 together, an anode 21 of at least one of the plurality of sub-pixels 20 is connected to the signal line 11 through the anode hole A.

As shown in FIG. 1, the anode hole A is arranged below the isolation structure 40 at a corner of adjacent sub-pixels 20, and the anode hole A provides signal connection for the sub-pixels 20. Please referring to FIG. 7 and FIG. 8 together, the signal line 11 corresponding to the substrate 10 and the anode 21 in the sub-pixel 20 are connected by the anode lead 12 through the corresponding anode hole A.

It can be understood that the substrate 10 plays a role in supporting an entire panel in the display panel 100. The substrate 10 is generally divided into two types: a hard substrate and a soft substrate. The hard substrate is usually made of a rigid material such as glass or plastic, with good stability and durability, suitable for a large-sized display and a professional display. The soft substrate is usually made of a soft material such as plastic or metal foil, suitable for a flexible display and a wearable device. The quality and performance of the substrate 10 directly affect the display effect and the service life of the display, so the selection of the substrate 10 is particularly important when manufacturing and selecting the display panel 100. A material of packaging the substrate 10 can include a hard packaging substrate and a flexible packaging substrate, and the selection of material includes but is not limited to BT material, ABF material, MIS material, PI (polyimide) and PE (polyester) resin or combinations thereof.

The sub-pixel 20 of the display panel 100 is a basic unit that makes up pixels in the display screen. In a liquid crystal display screen, a pixel is usually composed of three sub-pixels 20, such as brightness adjustment units for red, green, and blue. By adjusting brightness of three color sub-pixels 20 in different combinations, various colors can be presented, thereby displaying a color image on the display screen. Arrangement of the sub-pixels 20 is usually an alternating arrangement red, green, and blue, also known as RGB arrangement. For the sub-pixel 20 in the liquid crystal display panel 100, a main material used include a transparent conductive material, a liquid crystal material, and a filter. The transparent conductive material is mainly used as an electrode to transmit a signal and control a current. The liquid crystal material is used to control degree of light penetration and achieve brightness adjustment of the pixel. The filter is used to filter light of specific color, ensuring the accuracy of a displayed color. Specifically, in some embodiments, referring to FIGS. 5 and 6 together, the sub-pixel 20 includes an anode 21, a light-emitting layer 22, and a cathode 23 stacked in sequence. Specifically, in one embodiment, the plurality of sub-pixels 20 include three primary colors of red, green, and blue (RGB), that is, each color in each pixel is called the sub-pixel 20, and each sub-pixel 20 emits light of different colors, such as red, blue, or green, through the light-emitting layer 22 when powered on.

An anode material of the anode 21 is mainly used as the anode of a device, requiring a work function to be as high as possible to improve hole injection efficiency. The anode material includes but is not limited to chromium, titanium, gold, silver, copper, aluminum, ITO, combinations thereof or other suitable conductive materials.

A cathode material of cathode 23 is mainly used as the cathode of the device. The lower the metal work function of the cathode material, the easier the electron injection, the higher the luminous efficiency, the less the Joule heat generated during operation, and the significantly improved service life of the device. The cathode material includes but is not limited to chromium, titanium, gold, silver, copper, aluminum, ITO, combinations thereof or other suitable conductive materials. The cathode material and the anode material can be the same material or different materials, and can be set according to actual needs.

The light-emitting layer 22 may include one or more of a Hole Injection Layer (HIL), a Hole Transfer Layer (HTL), an Emission Layer (EML), and an Electron Transfer Layer (ETL). Organic light-emitting materials in the light-emitting layer 22 are generally divided into two categories: high molecular weight polymer, small molecule organic compound, and complex light-emitting material. The high molecular weight polymer is usually a conductive conjugated polymer or a semiconductor conjugated polymer, which can be formed into a film by a spin coating method. The production is simple and the cost is low, but it is not easy to improve purity, and the high molecular weight polymer is inferior to small-molecule organic compounds in terms of durability, brightness, and color. The organic small molecule light-emitting material is mainly an organic dye, which has strong chemical modification, wide selection range, easy purification, high quantum efficiency, and can produce various color emission peaks such as red, green, blue, yellow, etc. However, most of the organic small molecule light-emitting material has problems such as concentration quenching in a solid state. The complex light-emitting material is intermediate between the organic and inorganic materials, possessing both high fluorescence quantum efficiency of an organic compound and high stability of an inorganic compound, and is considered as a promising class of a light-emitting material.

The pixel defining layer 30 is configured to define an opening of the sub-pixel 20 in the display panel 100 to avoid color interference thereof. A material of the pixel defining layer 30 can be one of an organic material, an organic material with an inorganic coating thereon, and an inorganic material. The organic material of the pixel defining layer 30 may include but be not limited to polyimide. The inorganic material of the pixel defining layer 30 may include but be not limited to silicon oxide (SiO₂), silicon nitride (Si₃N₄), silicon oxynitride (Si₂N₂O), magnesium fluoride (MgF₂), or combinations thereof.

Alternatively, in one embodiment, as shown in FIG. 1, the isolation structure 40 along the first direction and the isolation structure 40 along the second direction are connected to isolate the plurality of sub-pixels 20. The anode 21 of the sub-pixel 20 adjacent to the first chamfer structure E1 is provided with a second chamfer structure E2. in one embodiment, chamfer sizes between the first chamfer structures E1 or between the second chamfer structures E2 may be the same or different sizes. Similarly, the chamfer sizes between the first chamfer structure E1 and the second chamfer structure E2 may be the same or different, which can be set according to actual design requirements and are not specifically limited herein. For example, the chamfer size of one sub-pixel 20 is 4 μm, while the chamfer sizes of the other two adjacent sub-pixels 20 are 5 μm.

Alternatively, in one embodiment, the first chamfer structure E1 is a linear chamfer or arc-shaped chamfer, and the second chamfer structure E2 is a linear chamfer or arc-shaped chamfer. As shown in FIG. 1 and FIG. 2, FIG. 2 is a top view of a second embodiment of a display panel according to the present disclosure. It can be understood that for a chamfered structure, in order to increase the size at a connection part, a size of the anode hole A can be better designed. The diameter of the anode hole A should be smaller than a size of the connection part formed by the pixel defining layer 30 and the isolation structure 40.

Alternatively, in one embodiment, as shown in FIG. 1, the isolation structure 40 along the first direction and the isolation structure 40 along the second direction are connected to isolate four sub-pixels 20. A line connecting two adjacent sub-pixels 20 among the four sub-pixels 20 is defined as a first reference line, and a line connecting two diagonal sub-pixels 20 among the four sub-pixels 20 is defined as the second reference line. A width of the isolation structure 40 along the second reference line is greater than \sqrt{2} times the width of the isolation structure 40 along the first reference line.

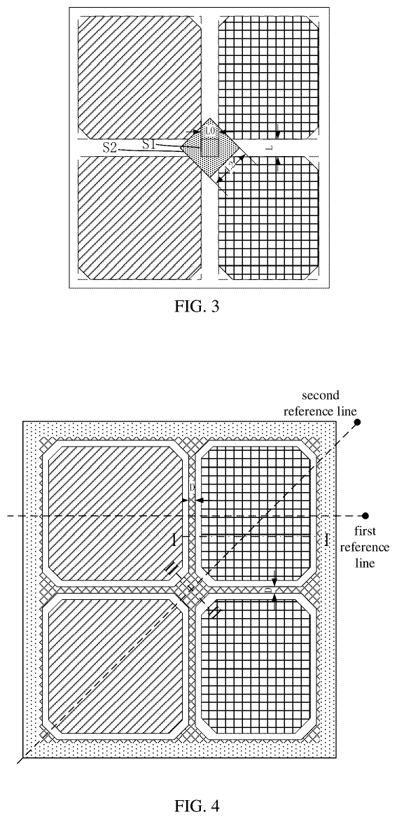

It can be understood that, in the above structural solution, as shown in FIG. 3, FIG. 3 is a schematic view of a first example structure of FIG. 1. Chamfering processing is carried out on the sub-pixels 20 and the defining layer 30, the anode hole A is arranged in the shielding area formed between the first chamfering structure E1 and the corresponding isolation structure 40 of the diagonal sub-pixels 20. It can be understood that, when no chamfer is provided, a coverage area of the pixel defining layer 30 of the first chamfer structure E1 between adjacent sub-pixels 20 is S1, which is the connection part described above. For example, in one embodiment, S1 is a square area with a side length of L0, and a coverage spacing of the pixel defining layer 30 between two adjacent sub-pixels 20 is L1. Specifically, in one embodiment, L1 is less than or equal to 15 μm, L0=L1. In other embodiments, when the chamfer sizes between the adjacent sub-pixels 20 are different, the coverage area S1 is a quadrilateral. For example, when the chamfers between the adjacent sub-pixels 20 are inverted right angles and the chamfer sizes are the same, an extension line of the chamfer between the adjacent sub-pixels 20 forms an S2 area, and S2 is a square area with a side length of L2, where L2 is \sqrt{2} times greater than L0.

Alternatively, in one embodiment, as shown in FIGS. 4, 5, and 6, FIG. 4 is a schematic view of a second example structure of FIG. 1; FIG. 5 is a cross-sectional schematic view of a sub-pixel I-I area in FIG. 4; FIG. 6 is a cross-sectional schematic view of a sub-pixel II-II area in FIG. 4. The isolation structure 40 includes a body 41 and a top portion 42. The top portion 42 is arranged on a side of the body 41 away from the pixel defining layer 30, and extends from both sides of the body 41 to form an overhanging portion. A width of the overhanging portion along the first reference line is equal to a width of the overhanging portion along the second reference line.

Alternatively, in one embodiment, a spacing between an edge of the overhanging portion and an edge of the pixel defining layer 30 along the first reference line is equal to a spacing between an edge of the overhanging portion and an edge of the pixel defining layer 30 along the second reference line.

It can be understood that, as shown in FIG. 5, a coverage distance of the pixel defining layer 30 between adjacent sub-pixels 20 is D1, and a width of the top potion 42 is D2. A distance between an edge end of the body 41 in contact with the top potion 42 and an edge end of the top potion 42 close to the pixel defining layer 30 on the same side is X1, and a distance between the edge end of the top potion 42 close to the pixel defining layer and the coverage edge of the pixel defining layer 30 on the same side is Y1. For example, in one embodiment, Y1 is less than or equal to 5 μm. in one embodiment, as shown in FIG. 6, in the II-II area, the coverage distance of the pixel defining layer 30 between adjacent sub-pixels 20 in the isolation structure 40 is D3, and the width of the top potion 42 is D4. The distance between the edge end of the body 41 in contact with the top potion 42 and an edge end of the top potion 42 close to the pixel defining layer 30 on the same side is X2, and the distance between the edge end of the top potion 42 close to the pixel defining layer and the coverage edge of the pixel defining layer 30 on the same side is Y2, X1=X2, Y1=Y2. In one embodiment, for the setting of the anode hole A, the diameter should be smaller than the width of the isolation structure 40, and when the anode lead 12 is covered above the corresponding anode hole A, the width of the anode lead 12 cannot be short circuited with the anode of the adjacent sub-pixel 20. Therefore, the width of the anode lead 12 needs to be smaller than the width of the top potion 42 of the isolation structure 40. In other embodiments, the width of the anode lead 12 may also be greater than the width of the top potion 42 of the isolation structure 40, but it is necessary to ensure that the anode lead 12 is separated from the adjacent sub-pixel 20 by an insulated pixel defining layer 30.

The isolation structure 40 separates the adjacent sub-pixels 20 to avoid cathode conduction and color interference between the adjacent sub-pixels 20, in order to better solve the problems of low resolution and low yield of the panel device. A material of the body 41 is a conductive metal or other metal oxide. For example, the material of the body 41 can include but is not limited to a conductive metal or other metal oxides such as aluminum (Al), magnesium (Mg), copper (Cu), silver (Ag), indium tin oxide (ITO), indium zinc oxide (IGZO), or combinations thereof, as long as they meet the usage conditions of the implementation scheme, and are not specifically limited here. A material of the top potion 42 is an insulating material, for example, which can include but is not limited to materials such as silicon monoxide (SiO), silicon dioxide (SiO₂), silicon nitride (SiNₓ), silicon oxynitride (SiNO), etc.

In the above embodiment, due to the presence of anode hole A, as shown in FIGS. 7 and 8, FIG. 7 is a cross-sectional schematic view of a sub-pixel III-III area in FIG. 1 according to a first embodiment; FIG. 8 is a cross-sectional schematic view of a sub-pixel III-III area in FIG. 1 according to a second embodiment. When the anode hole A is relatively deep, but due to a thickness of the pixel defining layer 30 being thin, after the anode hole A is filled, deposition will occur at a position of the anode hole A, resulting in a smaller pit appearing on a surface of the isolation structure 40. However, in the embodiment, the width of the upper isolation structure 40 on both sides is greater than the diameter of the anode hole A, so the pit will only concave in the middle of the isolation structure 40 and will not affect the stability of the overall structure of the display panel 100 or the function of evaporation.

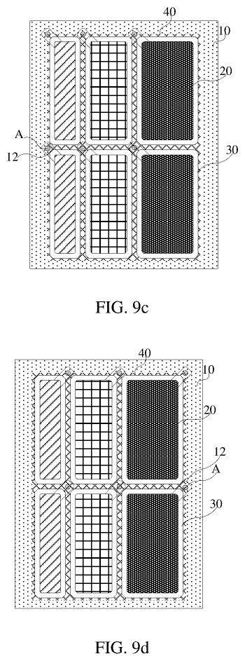

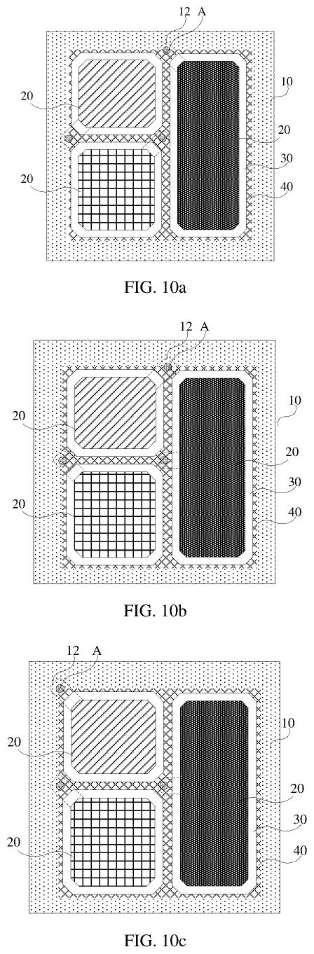

In the above embodiments, there are different arrangement schemes for the sub-pixels 20 in different arrangements. Specifically, for example, in one embodiment, the arrangement of the strip-shaped sub-pixels 20 is shown in FIGS. 9a to 9d. FIGS. 9a to 9d are schematic views of positions of anode holes A in sub-pixel arrangement of a display panel according to a first embodiment of the present disclosure. Specifically, for the arrangement of rectangular pixels similar to quadrilaterals, the anode hole A can be arranged at different directional positions. It can be understood that, as shown in FIGS. 9a to 9d, the anode hole A is arranged at an upper left corner, a lower left corner, an upper right corner, or a lower right corner of the plurality of sub-pixels 20, below the overhanging structure corresponding to an overlapping part of the first direction and the second direction mentioned above. Correspondingly, the anode lead 12 is configured to connect the anode 21 and the signal line 11 through the anode hole A. In another embodiment, for a T-shaped arrangement similar to a shape of the Chinese character “pin” ( [symbol] ), as shown in FIGS. 10a-10c. FIGS. 10a-10c are schematic views of positions of anode holes A in sub-pixel arrangement of a display panel according to a second embodiment of the present disclosure. Alternatively, in one embodiment, the isolation structure 40 along the first direction and the isolation structure 40 along the second direction are connected to isolate the three sub-pixels 20. As shown in FIGS. 10a-10c, among the three sub-pixels 20, the left two sub-pixels 20 are arranged vertically and then side by side with the right sub-pixel 20, forming a pixel arrangement similar to the shape of the Chinese character “pin”. The isolation structure 40 along the first direction and the isolation structure 40 along the second direction are connected to form a T-shaped structure area. As shown in FIG. 10a, an upper left sub-pixel 20 has an anode hole A in a lower left corner thereof, a lower left sub-pixel 20 has an anode hole A in an upper right corner thereof, and a right sub-pixel 20 has an anode hole A in an upper left corner thereof. Each sub-pixel 20 uses the anode lead 12 to connect the anode 21 and the signal line 11 in the substrate 10 through the anode hole A. As shown in FIG. 10b, the upper left sub-pixel 20 has an anode hole A in the upper right corner thereof, the lower left sub-pixel 20 has the anode hole A in the upper left corner thereof, and the right sub-pixel 20 has an anode hole A in the T-shaped junction area in middle. Each sub-pixel 20 uses the anode lead 12 to connect to the anode 21 and the signal line 11 in the substrate 10 through the anode hole A. As shown in FIG. 10c, the upper left sub-pixel 20 has an anode hole A in the upper left corner thereof, the lower left sub-pixel 20 has an anode hole A in the upper left corner thereof, and the right sub-pixel 20 has an anode hole A in the T-shaped junction area in the middle. Each sub-pixel 20 uses the anode lead 12 to connect to the anode 21 and the signal line 11 in the substrate 10 through the anode hole A.

It can be understood that, in the above mentioned sub-pixels 20, as shown in FIGS. 9a to 9d and FIGS. 10a to 10c, the sub-pixels 20 set therein all take the linear chamfer as an example. In other embodiments, the sub-pixels 20 can also be formed with arc-shaped chamfers, as shown in FIG. 2, and the corresponding arrangement and the setting mode of the anode hole A are the same.

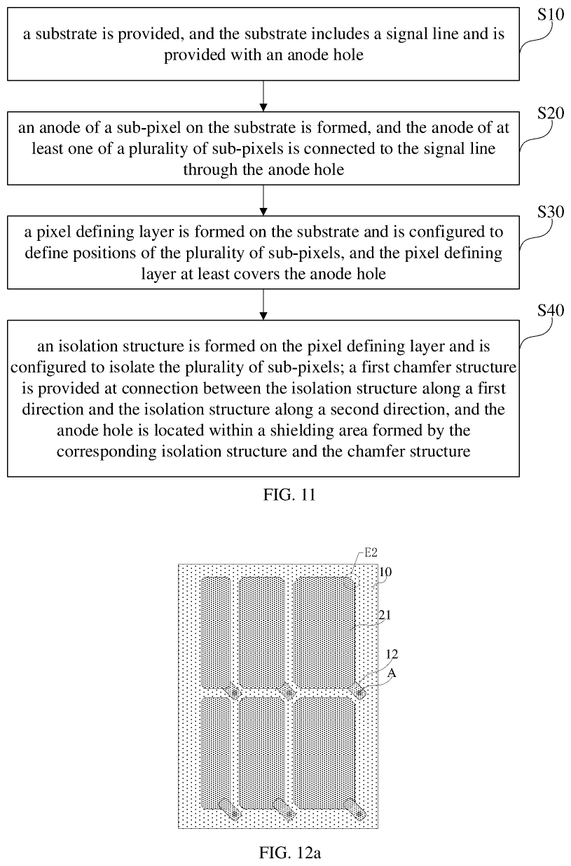

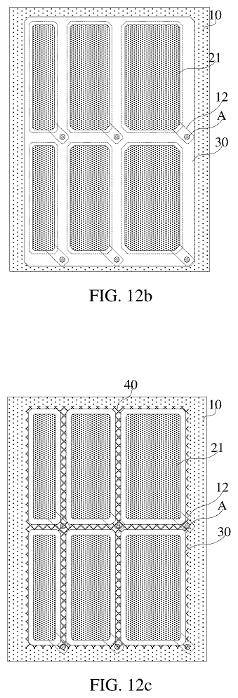

In order to solve the above problems, the present disclosure also provides a manufacturing method of the display panel 100, as shown in FIG. 11 and FIGS. 12a-12c. FIG. 11 is a flowchart of an embodiment of a manufacturing method of the display panel according to the present disclosure; FIGS. 12a-12c are schematic views of a process in FIG. 11. Specifically, the manufacturing method of the display panel 100 includes the following operations.

At block S10, a substrate is provided, and the substrate includes a signal line and is provided with an anode hole.

It can be understood that, as shown in FIG. 12a, an anode hole A is located in the substrate 10, and the signal line 11 in the substrate 10 is connected to the anode 21 in the sub-pixel 20 through the anode hole A to achieve signal transmission and control of the display screen. For example, the substrate 10 is a Thin Film Transistor (TFT) substrate.

At block S20, an anode of a sub-pixel on the substrate is formed, and the anode of at least one of a plurality of sub-pixels is connected to the signal line through the anode hole.

As shown in FIG. 12b, the structural material of the anode 21 is the same as that in the above embodiments, and will not be further described here. On the basis of forming the anode 21, the anode 21 is chamfered to form a second chamfer structure E2 to reserve a position of the anode hole A.

At block S30, a pixel defining layer is formed on the substrate and is configured to define positions of the plurality of sub-pixels, and the pixel defining layer at least covers the anode hole.

As shown in FIG. 12c, the pixel defining layer 30 is configured to define the openings of the plurality of sub-pixels 20 in the display panel 100 to avoid color interference among them. The material of the pixel defining layer 30 can be one of an organic material, an organic material with an inorganic coating thereon, and an inorganic material. The organic material of the pixel defining layer 30 includes but is not limited to polyimide. The inorganic material of the pixel defining layer 30 include but are not limited to silicon oxide (SiO₂), silicon nitride (Si₃N₄), silicon oxynitride (Si₂N₂O), magnesium fluoride (MgF₂), or combinations thereof. Chamfering design can also be applied to the pixel defining layer 30 to reserve enough space for the anode hole A and improve the aperture ratio.

At block S40, an isolation structure is formed on the pixel defining layer and is configured to isolate the plurality of sub-pixels; a first chamfer structure is provided at connection between the isolation structure along a first direction and the isolation structure along a second direction, and the anode hole is located in a shielding area formed by the corresponding isolation structure and the chamfer structure.

As shown in FIGS. 7 and 12c, the isolation structure 40 includes a body 41 and a top portion 42, and the body 41 and the top portion 42 are sequentially formed on the pixel defining layer 30. A material used for the body 41 is a conductive metal or other metal oxides. For example, the material used for the body 41 can include but is not limited to conductive metals such as aluminum (Al), magnesium (Mg), copper (Cu), silver (Ag), indium tin oxide (ITO), indium zinc oxide (IGZO), or other metal oxides or combinations thereof, which only need to meet the usage conditions of the implementation scheme, and are not specifically limited here. A material of the top potion 42 is an insulating material, which can include but is not limited to materials such as silicon monoxide (SiO), silicon dioxide (SiO₂), silicon nitride (SiNₓ), silicon oxynitride (SiNO), etc.

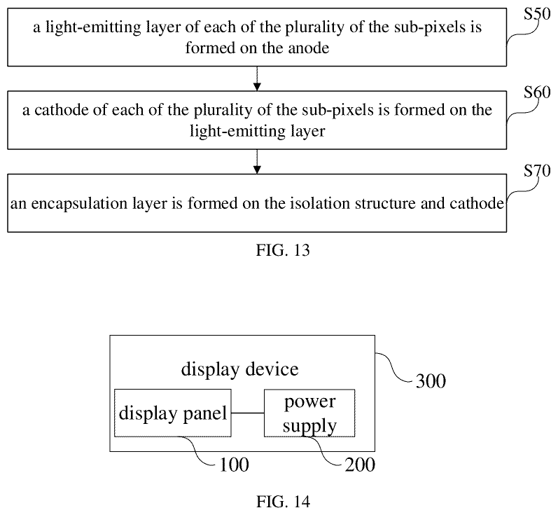

As shown in FIG. 13, FIG. 13 is a flowchart of subsequent operations after operations at block S40 in FIG. 11. Specifically, after forming the isolation structure 40 on the pixel defining layer 30, the method further includes the following operations.

At block S50, a light-emitting layer of each of the plurality of the sub-pixels is formed on the anode.

The light-emitting layer 22 can emit different colors, such as the three primary colors of red, green, and blue (RGB), to emit light of different colors when the light-emitting layer 22 is powered on.

At block S60, a cathode of each of the plurality of the sub-pixels is formed on the light-emitting layer.

As shown in FIG. 7, a material of cathode 23 can include but is not limited to chromium, titanium, gold, silver, copper, aluminum, ITO, combinations thereof or other suitable conductive materials. The cathode 23 material and the anode 21 material can be the same material or different materials, and can be arranged according to actual needs.

At block S70, an encapsulation layer is formed on the isolation structure and cathode.

The encapsulation layer is mainly configured to protect and isolate between each sub-pixel 20, protect its structure and prevent crosstalk, and isolate it from the external environment, so as to avoid the pollution and corrosion of the display panel 100 by substances such as impurities, oxygen, and moisture in the air, and avoid problems such as damage by external forces. A packaging method may include but are not limited to chemical vapor deposition (CVD), atomic layer deposition (ALD), and mixed barrier layers.

Traditional packaging technology involves encapsulating electrodes and various organic functional layers on a rigid substrate. Typically, a cover plate is added to the device and a desiccant is attached, and then the substrate and the cover plate are combined through a sealant such as epoxy resin. Thin film packaging is currently the mainstream technology for packaging. Thin film packaging materials are mainly divided into an inorganic packaging material, an organic packaging material, and an inorganic-organic composite packaging material. The inorganic organic composite packaging material has the advantages of good water and oxygen barrier properties of the inorganic packaging material and good film-forming properties of the organic packaging material, and are the mainstream choice of the packaging material. The key core material of OLED device is the ultra-thin organic electrolight-emitting layer 22, which is extremely sensitive to water, oxygen, and heat, which is also the reason for its poor stability. Therefore, after the production of the display panel 100 is completed, the encapsulation layer is usually formed on this basis to protect the display panel 100 and extend the service life of the display panel 100.

In order to solve the above problems, the present disclosure also provides a display device, as shown in FIG. 14. FIG. 14 is a schematic view of an embodiment of a display device according to the present disclosure. The display device 300 includes a display panel 100 and a power supply 200. The display panel is the display panel 100 as described in any one of the above embodiments or the display panel 100 manufactured by the above manufacturing method. The power supply 200 supplies power to the display panel to provide stable image output to the display device 300 through the display panel 100.

The display panel 100 according to the present disclosure includes: a substrate 10, a sub-pixel 20, a pixel defining layer 30, and an isolation structure 40. Specifically, the substrate 10 includes a signal line 11. A plurality of sub-pixels 20 are arranged on the substrate 10, and each of the plurality of sub-pixels 20 at least includes an anode 21; a pixel defining layer 30 arranged on the substrate 10, and configured to limit positions of the plurality of sub-pixels 20; an isolation structure 40 arranged on a side of pixel defining layer 30 away from substrate 10, and configured to isolate the plurality of sub-pixels 20. The isolation structure 40 along a first direction and the isolation structure 40 along a second direction are connected to form a connection part, and the connection part includes an overlapping part corresponding to both the first direction and the second direction, as well as a chamfered part corresponding to an angle between the first direction and the second direction. The connection part forms a projection area on the substrate 10, and the substrate 10 is provided with an anode hole A located in the projection area. At least one anode 21 among the adjacent anodes 21 of the connection part is connected to the signal line 11 through the anode hole A.

Through the above methods, the structure and position of the isolation structure combined with the anode hole are optimized to occupy the non-luminous area in the display panel, improve the light-emitting effect of the display panel, and increase the aperture ratio and the utilization rate of the display area.

The embodiments of the present disclosure have been described in detail above. The principles and implementations of the present disclosure are described in the specific examples. The description of the above embodiments is only used to help understanding the methods of the present disclosure and the core ideas. For those skilled in the art, there will have a change in the specific embodiments and the application scope of present disclosure according to the idea of the present disclosure. In summary, the content of the present specification should not be construed as limiting the present disclosure.

1. A display panel, comprising:
a substrate, comprising a signal line;
a plurality of sub-pixels, arranged on the substrate;
a pixel defining layer, arranged on the substrate, and configured to limit positions of the plurality of sub-pixels;
an isolation structure, arranged on a side of the pixel defining layer away from the substrate, and configured to isolate the plurality of sub-pixels;
wherein a first chamfer structure is provided at connection between the isolation structure along the first direction and the isolation structure along the second direction, and the substrate is provided with an anode hole located in a shielding area formed by a corresponding isolation structure and the first chamfer structure, and an anode of at least one of the plurality of sub-pixels is connected to the signal line through the anode hole.

2. The display panel as claimed in claim 1, wherein the isolation structure along the first direction and the isolation structure along the second direction are connected to isolate the plurality of sub-pixels; and
an anode of each of the plurality of sub-pixels adjacent to the first chamfer structure is provided with a second chamfer structure.

3. The display panel as claimed in claim 2, wherein the isolation structure along the first direction and the isolation structure along the second direction are connected to isolate four of the plurality of sub-pixels; and
a line connecting two adjacent sub-pixels among the four of the plurality of sub-pixels is defined as a first reference line, and a line connecting two diagonal sub-pixels among the four of the plurality of sub-pixels is defined as a second reference line; a width of the isolation structure along the second reference line is \sqrt{2} times greater than the width of the isolation structure along the first reference line.

4. The display panel as claimed in claim 3, wherein the isolation structure comprises a body and a top potion, wherein the top potion is arranged on one side of the body away from the pixel defining layer, and the top potion extends from both sides of the body to form a overhanging portion; and
a width of the overhanging portion along the first reference line is equal to a width of the overhanging portion along the second reference line.

5. The display panel as claimed in claim 4, wherein a spacing between an edge of the overhanging portion and an edge of the pixel defining layer along the first reference line is equal to a spacing between the edge of the overhanging portion and the edge of the pixel defining layer along the second reference line.

6. The display panel as claimed in claim 4, wherein a diameter of the anode hole is smaller than the width of the isolation structure.

7. The display panel as claimed in claim 2, wherein the isolation structure along the first direction and the isolation structure along the second direction are connected to isolate three of the plurality of sub-pixels.

8. The display panel as claimed in claim 2, wherein the first chamfer structure is a linear chamfer or an arc-shaped chamfer, and the second chamfer structure is a linear chamfer or an arc-shaped chamfer.

9. The display panel as claimed in claim 8, wherein a diameter of the anode hole is smaller than a size of a connection part formed by the pixel defining layer and the isolation structure.

10. A manufacturing method of a display panel, comprising:
providing a substrate, wherein the substrate comprises a signal line, and is provided with an anode hole;
forming an anode of a sub-pixel on the substrate, wherein anode of at least one of a plurality of sub-pixels is connected to the signal line through the anode hole;
forming a pixel defining layer on the substrate, wherein the pixel defining layer is configured to define positions of the plurality of sub-pixels, and the pixel defining layer at least covers the anode hole;
forming an isolation structure on the pixel defining layer, wherein the isolation structure is configured to isolate the plurality of sub-pixels; a first chamfer structure is provided at connection between the isolation structure along the first direction and the isolation structure along the second direction, and the anode hole is located in a shielding area formed by the corresponding isolation structure and the chamfer structure.

11. The manufacturing method of the display panel as claimed in claim 10, wherein after forming the isolation structure on the pixel defining layer, the method further comprises:
forming a light-emitting layer of each of the plurality of sub-pixels on the anode;
forming a cathode of each of the plurality of sub-pixels on the light-emitting layer;
forming an encapsulation layer on the isolation structure and the cathode.

12. A display device, comprising a display panel and a power supply for supplying power to the display panel, wherein the display panel comprises:
a substrate, comprising a signal line;
a plurality of sub-pixels, arranged on the substrate;
a pixel defining layer, arranged on the substrate, and configured to limit positions of the plurality of sub-pixels;
an isolation structure, arranged on a side of the pixel defining layer away from the substrate, and configured to isolate the plurality of sub-pixels;
wherein a first chamfer structure is provided at connection between the isolation structure along the first direction and the isolation structure along the second direction, and the substrate is provided with an anode hole located in a shielding area formed by a corresponding isolation structure and the first chamfer structure, and an anode of at least one of the plurality of sub-pixels is connected to the signal line through the anode hole.

13. The display device as claimed in claim 12, wherein the isolation structure along the first direction and the isolation structure along the second direction are connected to isolate the plurality of sub-pixels; and
an anode of each of the plurality of sub-pixels adjacent to the first chamfer structure is provided with a second chamfer structure.

14. The display device as claimed in claim 13, wherein the isolation structure along the first direction and the isolation structure along the second direction are connected to isolate four of the plurality of sub-pixels; and
a line connecting two adjacent sub-pixels among the four of the plurality of sub-pixels is defined as a first reference line, and a line connecting two diagonal sub-pixels among the four of the plurality of sub-pixels is defined as a second reference line; a width of the isolation structure along the second reference line is \sqrt{2} times greater than the width of the isolation structure along the first reference line.

15. The display device as claimed in claim 14, wherein the isolation structure comprises a body and a top potion, wherein the top potion is arranged on one side of the body away from the pixel defining layer, and the top potion extends from both sides of the body to form a overhanging portion; and
a width of the overhanging portion along the first reference line is equal to a width of the overhanging portion along the second reference line.

16. The display device as claimed in claim 15, wherein a spacing between an edge of the overhanging portion and an edge of the pixel defining layer along the first reference line is equal to a spacing between the edge of the overhanging portion and the edge of the pixel defining layer along the second reference line.

17. The display device as claimed in claim 15, wherein a diameter of the anode hole is smaller than the width of the isolation structure.

18. The display device as claimed in claim 13, wherein the isolation structure along the first direction and the isolation structure along the second direction are connected to isolate three of the plurality of sub-pixels.

19. The display device as claimed in claim 13, wherein the first chamfer structure is a linear chamfer or an arc-shaped chamfer, and the second chamfer structure is a linear chamfer or an arc-shaped chamfer.

20. The display device as claimed in claim 19, wherein a diameter of the anode hole is smaller than a size of a connection part formed by the pixel defining layer and the isolation structure.
